(19) United States
(12) Patent Application Publication
(10) Pub. No.: US 2015/0380283 A1
(43) Pub. Date: Dec. 31, 2015

(54) PROCESSING APPARATUS

(71) Applicant: DISCO CORPORATION, Tokyo (JP)

(72) Inventor: Naoya Sukegawa, Tokyo (JP)

(21) Appl. No.: 14/749,965

(22) Filed: Jun. 25, 2015

(30) Foreign Application Priority Data
Jun. 27, 2014 (JP) 2014-132280

(51) Int. Cl. H01L 21/67; B24B 49/00; B24B 7/22

(52) U.S. Cl. CPC H01L 21/67092; B24B 7/228; B24B 49/00; H01L 21/67253

(57) ABSTRACT

A processing apparatus including a holding unit that holds a workpiece and a grinding unit that grinds the workpiece held by the holding unit is provided. The processing apparatus includes a gettering capability determining unit that determines whether or not grinding distortion generated by grinding the workpiece held by the holding unit by the grinding unit has sufficient gettering capability.

### BACKGROUND OF THE INVENTION

1. Field of the Invention

The present invention relates to processing apparatus that grinds a workpiece having a plate shape.

2. Description of the Related Art

In small-size, light-weight electronic apparatus typified by mobile phones, a device chip having a device such as an IC is an essential configuration. The device chip is manufactured by partitioning a surface of a wafer composed of a material such as silicon by plural planned dividing lines called streets and forming a device in each region and then dividing the wafer along the streets, for example.

In recent years, there are increasing opportunities to process a wafer on which devices have been formed (device wafer) into a thin wafer for the purpose of size reduction, weight reduction, and so forth of the device chip. However, for example when the device wafer is polished to be thinned to 100 μm or thinner, the gettering effect to suppress the movement of metal elements harmful to the devices is lowered and operation failure of the device frequently occurs. To solve this problem, a processing method in which a gettering layer that captures metal elements is formed in a device wafer has been proposed (refer to e.g. Japanese Patent Laid-open No. 2009-94326). In this processing method, the device wafer is ground under predetermined conditions to form the gettering layer including predetermined grinding distortion while keeping the flexural strength of the device wafer.

### SUMMARY OF THE INVENTION

However, the gettering layer formed by the above-described processing method does not always exhibit favorable gettering capability. For evaluation of the gettering capability of the gettering layer, a method of actually contaminating the device wafer with metal elements can be used for example. However, in this case, it becomes impossible to obtain a device chip as a non-defective product. That is, there is a problem that it is impossible to incorporate this evaluation method into the processing step of the device wafer.

Therefore, an object of the present invention is to provide processing apparatus that can evaluate the gettering capability of a workpiece in a processing step.

In accordance with an aspect of the present invention, there is provided processing apparatus including holding means for holding a workpiece and grinding means for grinding the workpiece held by the holding means. The processing apparatus includes gettering capability determining means for determining whether or not grinding distortion generated by grinding the workpiece held by the holding means by the grinding means has sufficient gettering capability.

In the present invention, the processing apparatus may further include grinding distortion removing means for removing part of the grinding distortion generated by grinding by the grinding means.

The processing apparatus according to the present invention includes the gettering capability determining means for determining whether or not the grinding distortion generated by grinding the workpiece has gettering capability in addition to the holding means for holding the workpiece and the grinding means for grinding the workpiece. Thus, the processing apparatus can evaluate the gettering capability of the workpiece in the processing step.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically showing processing apparatus according to an embodiment;

FIG. 2A is a perspective view schematically showing an example of a workpiece to be processed by the processing apparatus according to the embodiment;

FIG. 2B is a perspective view schematically showing how a protective member is stuck to the workpiece;

FIG. 3 is a perspective view schematically showing a grinding distortion removing unit included in the processing apparatus; and

FIG. 4 is a partially sectional side view schematically showing a gettering capability determining unit included in the processing apparatus.

### DETAILED DESCRIPTION OF THE PREFERRED EMBODIMENT

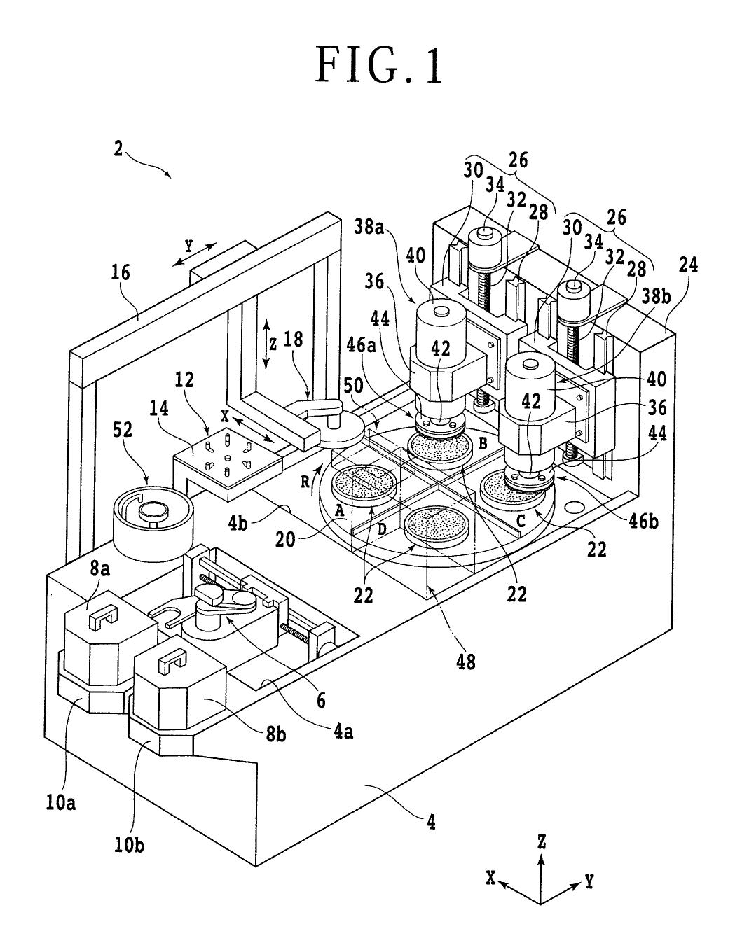

An embodiment of the present invention will be described with reference to the accompanying drawings. FIG. 1 is a perspective view schematically showing processing apparatus according to the present embodiment. As shown in FIG. 1, processing apparatus 2 includes a base 4 that supports the respective structures. An opening 4a is formed on the front end side of the upper surface of the base 4. In this opening 4a, a first conveying unit 6 that conveys a workpiece is provided. Furthermore, in a region on the front side of the opening 4a, placement tables 10a and 10b on which cassettes 8a and 8b that each can house plural workpieces are placed are formed.

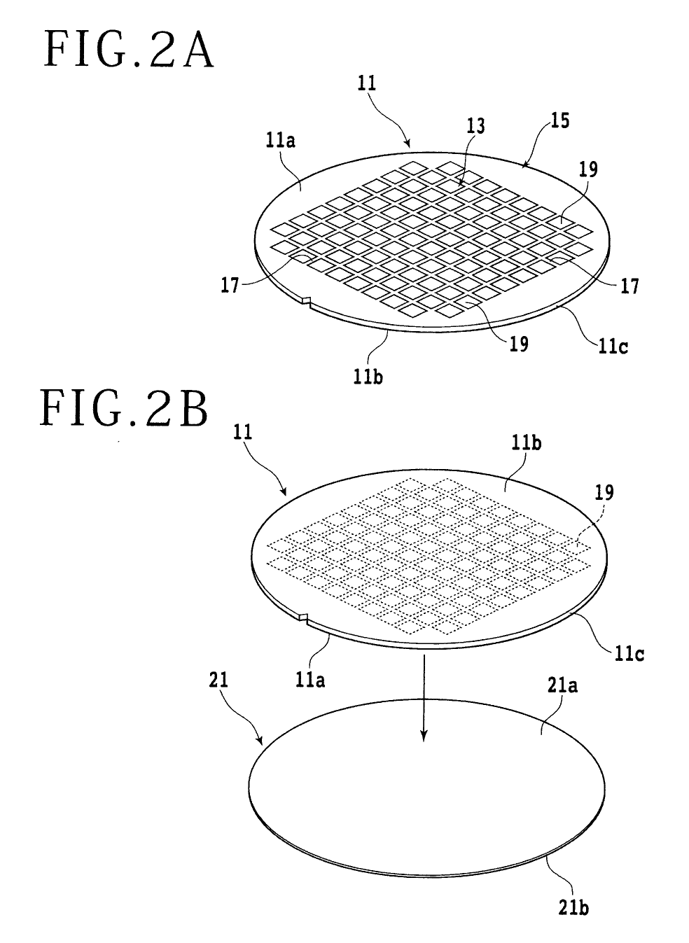

FIG. 2A is a perspective view schematically showing an example of a workpiece to be processed by the processing apparatus according to the present embodiment. As shown in FIG. 2A, a workpiece 11 is e.g. a plate-shaped object (wafer) that is formed by a semiconductor material such as silicon and has a substantially circular shape and a front surface 11a is divided into a device region 13 as a central region and a peripheral surplus region 15 surrounding the device region 13. The device region 13 is further partitioned into plural regions by streets (planned dividing lines) 17 arranged in a lattice manner and a device 19 such as an IC is formed in each region. Outer circumference 11c of the workpiece 11 is subjected to chamfering processing and is slightly rounded.

A protective member for protecting the devices 19 is stuck to the side of the front surface 11a of this workpiece 11. FIG. 2B is a perspective view schematically showing how the protective member is stuck to the workpiece 11. As shown in 2B, a protective member 21 is formed into a circular disk shape having substantially the same diameter as the workpiece 11 and an adhesive layer is provided on the side of a front surface 21a. As the protective member 21, e.g. an adhesive tape, a resin substrate, the same plate-shaped object (wafer) as the workpiece 11, etc. can be used. The side of the front surface 21a of this protective member 21 is made to face the side of the front surface 11a of the workpiece 11 and the protective member 21 and the workpiece 11 are overlapped with each other. This allows the protective member 21 to be stuck to the side of the front surface 11a of the workpiece 11 with the intermediary of the adhesive layer.

On an oblique rear side of the opening 4a, an alignment mechanism 12 that carries out position alignment of the workpiece 11 is provided. This alignment mechanism 12 includes a provisional placement table 14 on which the workpiece 11 is provisionally placed and carries out position alignment of the center of the workpiece 11 that is conveyed from the cassette 8a by the first conveying unit 6 and is provisionally placed on the provisional placement table 14 for example. A gate-shaped support structure 16 that straddles the alignment mechanism 12 is disposed on a side surface of the base 4. This support structure 16 is provided with a second conveying unit 18 that conveys the workpiece 11. The second conveying unit 18 can move in the left-right direction (X-axis direction), the front-rear direction (Y-axis direction), and the upward-downward direction (Z-axis direction), and conveys the workpiece 11 whose position has been aligned by the alignment mechanism 12 toward the rear side for example.

An opening 4b is formed on the rear side of the opening 4a and the alignment mechanism 12. In this opening 4b, a turn table 20 that rotates around a rotating axis extending along the vertical direction and has a circular disk shape is disposed. Four chuck tables (holding means) 22 that hold the workpiece 11 under suction are set at substantially equal angular intervals on the upper surface of the turn table 20. The workpiece 11 conveyed from the alignment mechanism 12 by the second conveying unit 18 is conveyed to the chuck table 22 positioned at a carry-in/carry-out position A on the front side, with the side of a back surface 11b exposed to the upper side. The turn table 20 rotates in a rotation direction R shown in the diagram to position each of the chuck tables 22 to the respective positions in order of the carry-in/carry-out position A, a coarse grinding position B, a finish grinding position C, and a grinding distortion removal position D. Each chuck table 22 is joined to a rotational drive source (not shown) such as a motor and rotates around a rotating axis extending along the vertical direction. The upper surface of each chuck table 22 serves as a holding surface to hold the workpiece 11 under suction. This holding surface is connected to a suction source (not shown) via a flow path (not shown) formed inside the chuck table 22. The side of the front surface 11a (side of the protective member 21) of the workpiece 11 conveyed to the chuck table 22 is sucked by a negative pressure by the suction source acting on the holding surface.

A wall-shaped support structure 24 extending upward is provided upright on the rear side of the turn table 20. Two lifting/lowering units 26 are provided on the front surface of the support structure 24. Each lifting/lowering unit 26 includes two lifting/lowering guide rails 28 extending along the vertical direction (Z-axis direction) and a lifting/lowering table 30 is slidably set on the lifting/lowering guide rails 28. A nut part (not shown) is fixed to the rear surface side (back surface side) of the lifting/lowering table 30 and a lifting/lowering ball screw 32 parallel to the lifting/lowering guide rails 28 is screwed to this nut part. A lifting/lowering pulse motor 34 is joined to one end part of the lifting/lowering ball screw 32. Rotating the lifting/lowering ball screw 32 by the lifting/lowering pulse motor 34 causes the lifting/lowering table 30 to move up and down along the lifting/lowering guide rails 28.

A fixing component 36 is provided on the front surface (surface) of the lifting/lowering table 30. A grinding unit (grinding means) 38a for coarse grinding of the workpiece 11 is fixed to the fixing component 36 of the lifting/lowering table 30 positioned above the coarse grinding position B. On the other hand, a grinding unit (grinding means) 38b for finish grinding of the workpiece 11 is fixed to the fixing component 36 of the lifting/lowering table 30 positioned above the finish grinding position C. A spindle 42 forming a rotating shaft is housed in each of spindle housings 40 of the grinding units 38a and 38b and a wheel mount 44 having a circular disk shape is fixed to the lower end part (tip part) of each spindle 42. A grinding wheel 46a having grinding stones for coarse grinding is mounted on the lower surface of the wheel mount 44 of the grinding unit 38a and a grinding wheel 46b having a grinding stones for finish grinding is mounted on the lower surface of the wheel mount 44 of the grinding unit 38b. A rotational drive source (not shown) such as a motor is joined to the upper end side of each spindle 42 and the grinding wheels 46a and 46b rotate by a rotational force transmitted from the rotational drive source. Coarse grinding or finish grinding of the workpiece 11 can be performed by, with the rotation of the chuck table 22 and the spindle 42, lowering the grinding wheel 46a or 46b and bringing it into contact with the side of the back surface 11b of the workpiece 11 while supplying a grinding solution such as purified water.

A grinding distortion removing unit (grinding distortion removing means) 48 that partly removes grinding distortion of the workpiece 11 ground by the grinding units 38a and 38b is provided near the grinding distortion removal position D. Furthermore, a gettering capability determining unit (gettering capability determining means) 50 that determines the gettering capability of the workpiece 11 is disposed above the carry-in/carry-out position A. The workpiece 11 ground by the grinding units 38a and 38b is subjected to partial removal of grinding distortion in the grinding distortion removing unit 48 and then is subjected to a determination about the gettering capability in the gettering capability determining unit 50. A cleaning unit 52 that cleans the workpiece 11 is provided on the front side of the alignment mechanism 12 and the workpiece 11 whose gettering capability has been determined is conveyed from the chuck table 22 to the cleaning unit 52 by the second conveying unit 18. The workpiece 11 cleaned by the cleaning unit 52 is conveyed to the first conveying unit 6 to be housed in the cassette 8b.

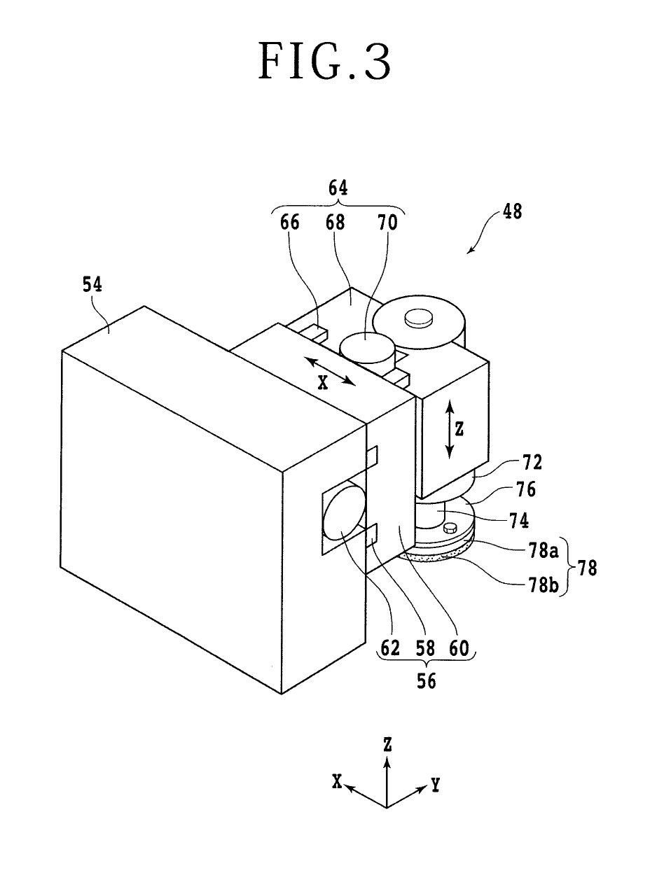

FIG. 3 is a perspective view schematically showing the grinding distortion removing unit 48 included in the processing apparatus 2. As shown in FIG. 3, a block-shaped support structure 54 is provided upright on the upper surface of the base 4. A horizontal movement unit 56 that moves the grinding distortion removing unit 48 in the horizontal direction (in this embodiment, X-axis direction) is provided on the rear surface of the support structure 54. The horizontal movement unit 56 includes a pair of horizontal guide rails 58 that are fixed to the rear surface of the support structure 54 and are in parallel to the horizontal direction (X-axis direction). A horizontal movement table 60 is slidably set on the horizontal guide rails 58. A nut part (not shown) is fixed to the front surface side of the horizontal movement table 60 and a horizontal ball screw (not shown) parallel to the horizontal guide rails 58 is screwed to this nut part. A pulse motor 62 is joined to one end part of the horizontal ball screw. Rotating the horizontal ball screw by the pulse motor 62 causes the horizontal movement table 60 to move in the horizontal direction (X-axis direction) along the horizontal guide rails 58.

A vertical movement unit 64 that moves the grinding distortion removing unit 48 in the vertical direction (Z-axis direction) is provided on the rear surface side of the horizontal movement table 60. The vertical movement unit 64 includes a pair of vertical guide rails 66 that are fixed to the rear surface of the horizontal movement table 60 and are in parallel to the vertical direction (Z-axis direction). A vertical movement table 68 is slidably set on the vertical guide rails 66. A nut part (not shown) is fixed to the front surface side (back surface side) of the vertical movement table 68 and a vertical ball screw (not shown) parallel to the vertical guide rails 66 is screwed to this nut part. A pulse motor 70 is joined to one end part of the vertical ball screw. Rotating the vertical ball screw by the pulse motor 70 causes the vertical movement table 68 to move in the vertical direction (Z-axis direction) along the vertical guide rails 66.

The grinding distortion removing unit 48 to partly remove the grinding distortion of the workpiece 11 is fixed to the rear surface (surface) of the vertical movement table 68. A spindle 74 forming a rotating shaft is housed in a spindle housing 72 of the grinding distortion removing unit 48 and a wheel mount 76 having a circular disk shape is fixed to the lower end part (tip part) of the spindle 74. A polishing wheel 78 having substantially the same diameter as the wheel mount 76 is mounted on the lower surface of the wheel mount 76. The polishing wheel 78 includes a wheel base 78a formed of a metal material such as stainless steel. A polishing pad 78b having a circular disk shape is fixed to the lower surface of the wheel base 78a. The grinding distortion of the workpiece 11 can be removed by, with the rotation of the chuck table 22 and the spindle 74, lowering the polishing wheel 78 and bringing the polishing pad 78b into contact with the side of the back surface 11b of the workpiece 11 while supplying a polishing solution. In this grinding distortion removing unit 48, the workpiece 11 is so polished that a certain level of grinding distortion remains. This can keep the flexural strength of the workpiece 11 while ensuring the gettering capability.

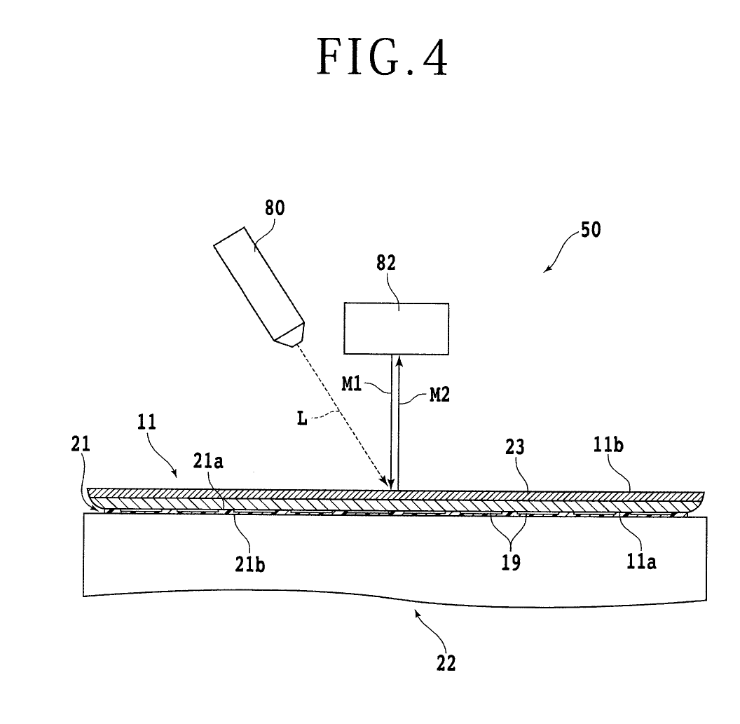

FIG. 4 is a partially sectional side view schematically showing the gettering capability determining unit 50 included in the processing apparatus 2. As shown in FIG. 4, the gettering capability determining unit 50 includes a laser beam irradiating unit 80 that irradiates the workpiece 11 positioned at the carry-in/carry-out position A with a pulse laser beam L having a predetermined wavelength (e.g. 904 nm, 532 nm, 349 nm, etc.). Near the laser beam irradiating unit 80, a microwave transmitting/receiving unit 82 that transmits (radiates) microwaves (electromagnetic waves) M1 toward the workpiece 11 and receives microwaves (electromagnetic waves) M2 reflected by the workpiece 11 is disposed. By this microwave transmitting/receiving unit 82, change in the intensity of the microwaves M2 reflected by the side of the back surface 11b of the workpiece 11 can be detected.

As shown in FIG. 4, in the case of determining the gettering capability of the workpiece 11 having a gettering layer 23 including predetermined grinding distortion, first, the microwaves (electromagnetic waves) M1 are transmitted (radiated) from the microwave transmitting/receiving unit 82 toward the back surface 11b of the workpiece 11. When, in this state, the region irradiated with the microwaves M1 is irradiated with the pulse laser beam L from the laser beam irradiating unit 80, excess carriers (electrons, holes) are generated on the side of the back surface 11b of the workpiece 11 and the reflectance of the microwaves M1 increases. That is, the intensity of the microwaves M2 received by the microwave transmitting/receiving unit 82 becomes higher. Thereafter, during the period when the irradiation with the pulse laser beam L is not performed, the reflectance of the microwaves M1 gradually decreases in association with the recombination of the carriers. That is, the microwaves M2 are gradually damped.

As a result of strenuous studies, the present inventor has found such a relationship that the lifetime of the carriers generated by the irradiation with the pulse laser beam L (time from generation of carriers to recombination) is shorter when the gettering capability of the gettering layer 23 is higher. Then, the present inventor has completed the present invention on the basis of an idea that the gettering capability can be evaluated by measuring the damping time of the microwaves M2 corresponding to the lifetime of the carriers. Specifically, the damping time of the microwaves M2 about the workpiece 11 as the evaluation target is measured and the gettering capability is evaluated by comparing this damping time with a predetermined reference time. As the reference time, the damping time of the microwaves M2 about a wafer in which the gettering layer 23 is not formed (bare wafer) can be used for example.

If the wavelength of the pulse laser beam L is set to 904 nm, the workpiece 11 whose damping time is equal to or shorter than 94% of the reference time is evaluated as having gettering capability for example. Furthermore, if the wavelength of the pulse laser beam L is set to 532 nm, the workpiece 11 whose damping time is equal to or shorter than 75% of the reference time is evaluated as having gettering capability. Moreover, if the wavelength of the pulse laser beam L is set to 349 nm, the workpiece 11 whose damping time is equal to or shorter than 45% of the reference time is evaluated as having gettering capability. However, the wavelength of the pulse laser beam L that can be used for this evaluation method is not limited to the above-described 904 nm, 532 nm, and 349 nm.

Furthermore, it is also possible to evaluate the flexural strength of the workpiece 11 by a similar method. If the wavelength of the pulse laser beam L is set to 904 nm, the workpiece 11 whose damping time is equal to or longer than 85% of the reference time is evaluated as having favorable flexural strength. Furthermore, if the wavelength of the pulse laser beam L is set to 532 nm, the workpiece 11 whose damping time is equal to or longer than 55% of the reference time is evaluated as having favorable flexural strength. Moreover, if the wavelength of the pulse laser beam L is set to 349 nm, the workpiece 11 whose damping time is equal to or longer than 20% of the reference time is evaluated as having favorable flexural strength. Also in the case of evaluating the flexural strength of the workpiece 11, the pulse laser beam L having a different wavelength from the above-described 904 nm, 532 nm, and 349 nm can be used.

If it is determined that the gettering capability of the workpiece 11 is insufficient by this gettering capability determining unit 50, it is preferable to carry out the respective steps of coarse grinding, finish grinding, and grinding distortion removal again to enhance the gettering capability of the workpiece 11.

Next, a description will be made about an experiment carried out in order to confirm the validity of the above-described determination carried out in the gettering capability determining unit 50.

### (Experiment)

In this experiment, the above-described damping time, the resistance against metal contamination, and the flexural strength were checked about the workpieces 11 in which the gettering layer 23 was formed under conditions different from each other (condition 1 to condition 10). The wavelengths of the pulse laser beam L radiated to the workpieces 11 were three kinds of wavelengths, 904 nm, 532 nm, and 349 nm. The experimental result when the wavelength of the pulse laser beam L was set to 904 nm is shown in table 1. The experimental result when the wavelength of the pulse laser beam L was set to 532 nm is shown in table 2. The experimental result when the wavelength of the pulse laser beam L was set to 349 nm is shown in table 3. In each table, “OK” represents the favorable state and “NG” represents the defective state. Furthermore, in each table, the experimental result of a wafer in which the gettering layer 23 was not formed (bare wafer) is shown as a reference.

TABLE 1

| | Damping | Metal | Flexural |
|---|---|---|---|
| | Time (%) | Contamination | Strength |
| Reference | 100 | NG | OK |
| Condition 1 | 87.4 | OK | OK |
| Condition 2 | 88.46 | OK | OK |
| Condition 3 | 88.46 | OK | OK |
| Condition 4 | 91.58 | OK | OK |
| Condition 5 | 90.24 | OK | OK |
| Condition 6 | 89.79 | OK | OK |
| Condition 7 | 94.04 | NG | OK |
| Condition 8 | 90.13 | OK | OK |
| Condition 9 | 105.12 | NG | OK |
| Condition 10 | 84.8 | OK | NG |

TABLE 2

| | Damping | Metal | Flexural |
|---|---|---|---|
| | Time (%) | Contamination | Strength |
| Reference | 100 | NG | OK |
| Condition 1 | 73.34 | OK | OK |
| Condition 2 | 61.02 | OK | OK |
| Condition 3 | 60.52 | OK | OK |
| Condition 4 | 62.88 | OK | OK |
| Condition 5 | 62.76 | OK | OK |
| Condition 6 | 60.14 | OK | OK |
| Condition 7 | 75.43 | NG | OK |
| Condition 8 | 57.65 | OK | OK |
| Condition 9 | 125.03 | NG | OK |
| Condition 10 | 54.72 | OK | NG |

TABLE 3

| | Damping | Metal | Flexural |
|---|---|---|---|
| | Time (%) | Contamination | Strength |
| Reference | 100 | NG | OK |
| Condition 1 | 21.59 | OK | OK |
| Condition 2 | 30.75 | OK | OK |
| Condition 3 | 35.21 | OK | OK |
| Condition 4 | 43.42 | OK | OK |
| Condition 5 | 42.95 | OK | OK |
| Condition 6 | 42.01 | OK | OK |
| Condition 7 | 45.12 | NG | OK |
| Condition 8 | 36.38 | OK | OK |
| Condition 9 | 114.7 | NG | OK |
| Condition 10 | 19.38 | OK | NG |

From the respective tables, it can be confirmed that the above-described determination is valid. For example, to ensure both the gettering capability and the flexural strength, the workpiece 11 is processed to satisfy the following condition. Specifically, when the wavelength is 904 nm, the damping time is equal to or longer than 85% of the reference time and is equal to or shorter than 94% of the reference time. When the wavelength is 532 nm, the damping time is equal to or longer than 55% of the reference time and is equal to or shorter than 75% of the reference time. When the wavelength is 349 nm, the damping time is equal to or longer than 20% of the reference time and is equal to or shorter than 45% of the reference time.

As described above, the processing apparatus 2 according to the present embodiment includes the gettering capability determining unit (gettering capability determining means) 50, which determines whether or not grinding distortion generated by grinding the workpiece 11 has gettering capability, in addition to the chuck tables (holding means) 22, which hold the workpiece 11, and the grinding units (grinding means) 38a and 38b, which grind the workpiece 11. Thus, the processing apparatus 2 can evaluate the gettering capability of the workpiece 11 in the processing step.

The present invention is not limited to the description of the above embodiment and can be carried out with various changes. For example, in the above embodiment, the damping time of the microwaves M2 about a wafer in which the gettering layer 23 is not formed (bare wafer) is used as the reference time. However, the reference time can be arbitrarily changed. For example, the damping time of the microwaves M2 about the workpiece 11 whose gettering capability is optimized may be used as the reference time. Furthermore, in the above embodiment, the microwave transmitting/receiving unit 82 integrally including the transmitting part that transmits (radiates) the microwaves M1 toward the workpiece 11 and the receiving part that receives the microwaves (electromagnetic waves) M2 reflected by the workpiece 11 is described. However, the transmitting part and the receiving part of the microwave transmitting/receiving unit may be separate parts. Moreover, in the above embodiment, the grinding distortion removing unit (grinding distortion removing means) 48, which polishes the workpiece 11 (typically CMP) to partly remove grinding distortion, is described. However, the grinding distortion removing unit (grinding distortion removing means) may be configured to remove grinding distortion by another method such as dry etching, wet etching, plasma etching, or dry polishing.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. Processing apparatus comprising:
holding means for holding a workpiece;
grinding means for grinding the workpiece held by the holding means; and
gettering capability determining means for determining whether or not grinding distortion generated by grinding the workpiece held by the holding means by the grinding means has gettering capability.

2. The processing apparatus according to claim 1, further comprising
grinding distortion removing means for removing part of the grinding distortion generated by grinding by the grinding means.
